(19) United States
(12) Patent Application Publication
(10) Pub. No.: US 2015/0137885 A1
(43) Pub. Date: May 21, 2015

(54) DUAL PATH RF AMPLIFIER CIRCUIT

(71) Applicant: AURIGA MEASUREMENT SYSTEMS, LLC, Chelmsford, MA (US)

(72) Inventor: Nickolas D. Kingsley, Andover, MA (US)

(21) Appl. No.: 14/543,371

(22) Filed: Nov. 17, 2014

Related U.S. Application Data
(60) Provisional application No. 61/905,624, filed on Nov. 18, 2013.

(51) Int. Cl. H03F 1/02; H03F 3/21; H03F 3/19

(52) U.S. Cl. CPC H03F 1/02; H03F 3/19; H03F 3/211; H03F 2200/451
USPC 330/124 R

(57) ABSTRACT

A dual path RF amplifier circuit including two or more amplifiers that are configurable as to any combination of class of operation, biasing, and power ratio to achieve a desired power curve for the amplifier circuit. In one example, an RF amplifier circuit includes an input coupler that generates at least two coupled signals from an RF input signal, first and second RF amplifiers each configured to receive and amplify one of the coupled signals to generate first and second amplified signals, and an output coupler generate an amplified output signal based on the first and second amplified signals. The first RF amplifier is biased into a first class of operation, and the second RF amplifier is biased into a second class of operation, wherein a power ratio between the first and second RF amplifiers is selected based on the amplifier biasing and the first and second classes of operation.

### CROSS-REFERENCE TO RELATED APPLICATIONS

This application claims the benefit under 35 U.S.C. §119(e) of co-pending U.S. Provisional Patent Application No. 61/905,624 titled “DUAL PATH RF AMPLIFIER CIRCUIT HAVING INCREASED POWER ADDED EFFICIENCY (PAE) AND INCREASED LINEARITY AT SATURATION” and filed on Nov. 18, 2013, which is herein incorporated by reference in its entirety.

### BACKGROUND

As is known in the art, radio frequency (RF) transmit systems commonly employ RF amplifying devices to convert low-power RF signals into larger-power RF signals. These larger-power RF signals can be used to drive an antenna of a transmitter, for example. One common RF amplifier design having relatively high power added efficiency (PAE) is called a Doherty amplifier. The Doherty amplifier is a modified class AB radio frequency (RF) amplifier, which is typically configured as a grounded-cathode, carrier-peak amplifier using two power transistors in parallel connection. One power transistor is typically configured as a class AB carrier amplifier, and the other as a class C peaking amplifier.

FIG. 1 illustrates an example of a conventional Doherty amplifier circuit. The conventional amplifier circuit 100 includes an equal power splitter (not shown), a carrier amplifier 110, and a peaking amplifier 120. The signal input to the peaking amplifier 120 is typically delayed by about 90° so that the peaking impedance is matched at back-off power levels. The signal output to the carrier amplifier 110 is typically delayed by about 90° so that the carrier impedance is matched at saturated power. The amount of current output from the peaking amplifier 120 as a load varies according to the input signal. One disadvantage with the conventional amplifier shown in FIG. 1 is that it relies on the 90° phase shifts to implement an impedance change to improve PAE at back-off and is therefore inherently narrowband because the phase shift is strongly frequency dependent. As a result, such conventional amplifiers are relatively band-width-limited and provide only a fraction of the available instantaneous bandwidth of the operating frequency.

### SUMMARY OF THE INVENTION

Aspects and embodiments relate generally to radio frequency (RF) circuits and, more particularly, to a dual path RF amplifier circuit having increased power added efficiency (PAE) and linearity at saturation.

Certain embodiments are directed to an amplifier circuit having two or more amplifiers in separate paths with a 1:N power ratio for the amplifier circuit with two amplifiers, using coupling ratios of [N/(N+1)] and [1/(N+1)] corresponding to amplifier ratios of 1 and N, while supporting multiple splitting/combining structures, providing a relatively low (and ideally minimum) third-order intermodulation (IM3) point at a power level near saturation of a designer's choosing, while also enabling re-configurability of a IM3 point at a particular power level by changing class, bias, and/or power ratio of the amplifiers of the amplifier circuit.

With this particular arrangement, an amplifier circuit having the above described features and also having increased PAE and linearity at saturation is provided.

According to one embodiment, an amplifier circuit includes an input coupler configured to receive one or more RF signals as an input and generate at least two coupled output signals as an output. The amplifier circuit can also include a first amplifier configured to receive one of the at least two coupled output signals as an input and generate a first amplified signal as an output. The amplifier circuit can additionally include a second amplifier configured to receive one of the at least two coupled output signals as an input and generate a second amplified signal as an output. The amplifier circuit can further include a output coupler configured to receive the first amplified signal and the second amplified signal as an input and generate an amplified output signal as an output, wherein the first amplifier and the second amplifier are configured to receive one of the at least two coupled output signals independent of the phase shift between the at least two coupled output signals, wherein the amplified output signal can be adjusted by changing any combination of a class, a bias, and a power ratio of the first amplifier and the second amplifier.

In another embodiment, an amplifier circuit includes an input coupler configured to receive one or more RF signals as an input and generate at least two coupled output signals as an output. The amplifier circuit can also include a plurality of amplifiers configured to receive one of the at least two coupled output signals as an input and generate a plurality of amplified signals as an output. The amplifier circuit can further include a output coupler configured to receive the plurality of amplified signals as an input and generate an amplified output signal as an output, wherein the plurality of amplifiers are configured to receive one of the at least two coupled output signals independent of the phase shift between the at least two coupled output signals, wherein the amplified output signal can be adjusted by changing any combination of a class, a bias, and a power ratio of the plurality of amplifiers.

According to one embodiment, a radio frequency (RF) amplifier circuit comprises an input coupler configured to receive an RF input signal and to generate at least two coupled signals, a first RF amplifier configured to receive and amplify a first one of the at least two coupled signals to generate a first amplified signal, the first RF amplifier being biased into a first class of operation, a second RF amplifier configured to receive and amplify a second one of the at least two coupled signals to generate a second amplified signal, the second RF amplifier being biased into a second class of operation, and an output coupler configured to receive the first and second amplified signals and to generate an amplified output signal based on the first and second amplified signals, wherein a power ratio between the first and second RF amplifiers is selected based on biasing of the first and second RF amplifiers, the first class of operation, and the second class of operation.

In one example, the first class of operation is one of class A, class AB, or class B, and the second class of operation is class C. In another example, the power ratio is 1:1. In one example, the input coupler and the output coupler are 3 dB couplers.

In another example, the first class of operation is the same as the second class of operation, the first RF amplifier has a normalized power rating of 1, and the second RF amplifier has a normalized power rating of N, such that the power ratio is 1:N. In one example, the input coupler has an input coupling factor selected to match the power ratio. In another example, the output coupler has an output coupling factor selected to match the power ratio.

In another example, the input coupler is configured to provide the first one of the at least two coupled signals at a first port with a coupling factor of N/(N+1), and to provide the second one of the at least two coupled signals at a second port with a coupling factor of 1/(N+1), wherein the first RF amplifier is connected to the first port to receive the first one of the at least two coupled signals, and the second RF amplifier is connected to the second port to receive the second one of the at least two coupled signals. In one example, the output coupler is a 3 dB coupler. In another example, the output coupler has a first input port connected to an output of the first RF amplifier to receive the first amplified signal, and a second input port connected to an output of the second RF amplifier to receive the second amplified signal, and the output coupler is configured with a coupling factor of N/(N+1) at the second input port and a coupling factor of [1−N/(N+1)] at the first input port. In another example, output coupler has a first input port connected to an output of the first RF amplifier to receive the first amplified signal, and a second input port connected to an output of the second RF amplifier to receive the second amplified signal, and the output coupler is configured with a coupling factor of 1/(N+1) at the second input port and a coupling factor of [1−1/(N+1)] at the first input port.

In one example, the first RF amplifier and the second RF amplifier are substantially the same and are biased differently such that the power ratio is less than or greater than one.

According to another embodiment an RF amplifier circuit comprises an input coupler configured to receive an RF input signal and to generate a plurality of coupled signals, a plurality of RF amplifiers each connected to the input coupler and configured to receive and amplify one of the plurality of coupled signals to generate a corresponding plurality of amplified signals, each of the plurality of RF amplifiers being configurable as to a class of operation and biasing, and an output coupler connected to the plurality of RF amplifiers and configured to receive the plurality of amplified signals and to generate an amplified output signal from the plurality of amplified signals, the amplified output signal being based on a combination of a selected class of operation of each of the plurality of RF amplifiers, the biasing of each of the plurality of RF amplifiers, and a power ratio between the plurality of RF amplifiers.

In one example, the plurality of RF amplifiers includes a first RF amplifier having a normalized power rating of 1, a second RF amplifier having a normalized power rating of X, and a third RF amplifier having a normalized power rating of Y, and wherein the power ratio is 1:X:Y. In another example, the input coupler has an input coupling factor selected to match the power ratio. In another example the output coupler has an output coupling factor selected to match the power ratio. In another example, the plurality of RF amplifiers are biased such that the power ratio is less than or greater than one.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a block diagram of an example of a conventional Doherty amplifier circuit;

FIG. 2 is a block diagram of one example of a dual path amplifier circuit including two amplifiers with a 1:N power ratio, according to aspects of the present invention;

FIG. 3 is a block diagram of another example of a dual path amplifier circuit including two amplifiers with a 1:N power ratio and using coupling ratios of N/(N+1) and 1/(N+1) corresponding to amplifier ratios of 1 and N, according to aspects of the present invention;

FIG. 4 is a graph of radio frequency (RF) output power as a function of RF input power, showing examples of power curves for the amplifiers and amplifier circuit of FIG. 2, according to aspects of the present invention; and

FIG. 5 is a graph of output power back-off from output saturation power (Psat) versus third order intermodulation product (IM3) amplitude, illustrating that examples of the amplifier circuits according to aspects of the present invention achieve linearity improvement deep into saturation while maintaining high efficiency.

### DETAILED DESCRIPTION

Aspects and embodiments are directed to a dual path RF amplifier circuit. According to certain embodiments, the RF amplifier circuit includes two amplifiers, particularly a carrier amplifier and a peaking amplifier, connected to provide dual paths between an input coupler and an output coupler. As discussed in more detail below, the two amplifiers may be independently controlled to reconfigure combinations of the class, bias, and/or power split ratio of the amplifiers, and to adjust the third-order intermodulation (IM3) point of the amplifier circuit to a desired input or output level. In particular, the two amplifiers may be controlled such that the output power of one amplifier becomes more substantial as the output of the other amplifier begins to compress due to saturation. With this arrangement, the amplifier circuit maintains linearity deep into saturation while also maintaining high efficiency, as discussed further below.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, and vertical and horizontal are intended for convenience of description, not to limit the present systems and methods or their components to any one positional or spatial orientation.

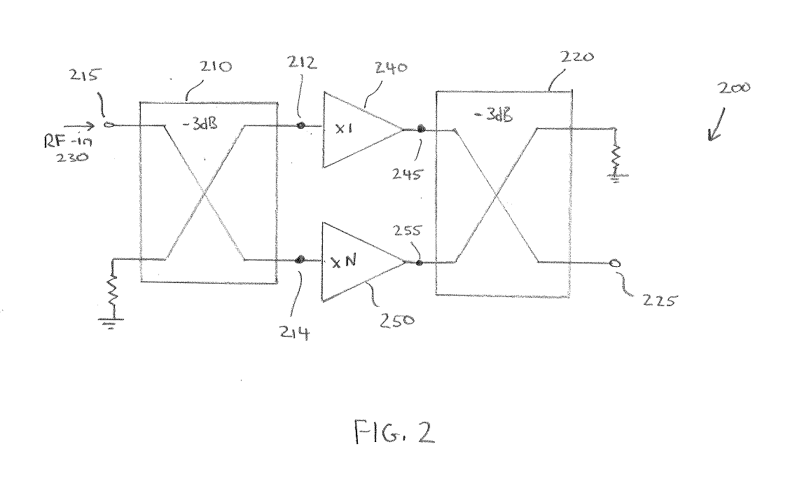

Referring to FIG. 2, there is illustrated one example of a dual path radio frequency (RF) amplifier circuit 200 having increased power added efficiency (PAE) and increased linearity at saturation at its output port 225.

The amplifier circuit 200 includes an input coupler 210 configured to receive an RF input signal 230 at an input port 215, and to generate input coupled signals at input coupler output ports 212, 214. In certain examples, the input coupled signals at input coupler output ports 212 and 214 may be out of phase depending upon, for example, the type of input coupler 210 used in the amplifier circuit 200. In some embodiments, the input coupler 210 may include Wilkinson power dividers, directional couplers, branch line couplers, balun transformers, and other power splitting or combining means known to those of skill in the art. Four port couplers can, for example, provide a 90° degree phase shift between the input coupled signals presented at input coupler output ports 212 and 214. Wilkinson power dividers and hybrid ring couplers, on the other hand, can provide a 0 or 180 degree phase shift between the input coupled signals presented at input coupler output ports 212 and 214. In the example illustrated in FIG. 2, the input coupled signals at input coupler output ports 212 and 214 may be of equal amplitude. However, in other examples the input coupler may be selected to provide signals with different amplitudes at the input coupler output ports 212 and 214, as discussed further below.

The input coupler output ports 212 and 214 are connected to the input ports of RF amplifiers 240 and 250, respectively, as shown in FIG. 2. The RF amplifiers 240 and 250 can be configured to receive and amplify the input coupled signals so as to generate first and second amplified signals at amplifier output ports 245, 255, respectively. In some embodiments, the RF amplifiers 240 and 250 are each configured to receive and amplify one of the input coupled signals from input coupler ports 212 and 214 substantially independent of any phase shift (e.g., 90° or not) between the input coupled signals, as discussed further below. The RF amplifiers 240 and 250 may be independently and selectively biased into the same or different classes of operation, for example, but not limited to, class A, B, AB, or C operation. As discussed further below, according to certain embodiments, RF amplifier 240 can be designed and biased to receive and amplify one of the input coupled signals from input coupler output port 212 or 214 having relatively low signal levels, and RF amplifier 250 can be designed and biased to receive and amplify the other of the two input coupled signals having relatively high input signal levels. As used herein, the term “relatively low signal levels” is intended to refer to any input power level at which the RF amplifier 240 is in the linear region if biased into class A, B, or AB operation, and any input power level at which the RF amplifier 240 has zero gain if biased into class C operation. As used herein, the term “relatively high signal levels” is intended to refer to any input power level at which the output power of the RF amplifier 250 does not increase in a 1:1 manner (i.e., compressing) if the RF amplifier 250 is biased into class A, B, or AB operation and any input power level at which the RF amplifier 250 has a gain if biased into class C operation.

The RF amplifiers 240 and 250 are connected to an output coupler 220, which is configured to receive the first and second amplified signals and to generate an amplified output signal with improved linearity substantially into saturation. The amplified output signal is provided at the output port 225 of amplifier circuit 200. According to certain embodiments, providing the amplified output signal with improved linearity substantially into saturation is achieved by controlling the class of operation, bias, and/or power ratio of the RF amplifiers 240 and 250.

Still referring to FIG. 2, in certain embodiments, the output power characteristics of the RF amplifiers 240 and 250 can be the same, and in other embodiments the output power characteristics of the RF amplifiers 240 and 250 may be different and represented by a power ratio of 1:N, where N represents the normalized power rating. For example, RF amplifier 240 may have an output power of 2 Watts (W) (i.e., RF amplifier 240 is capable of generating a 2 W RF output signal), while RF amplifier 250 may have an output power of 10 W (i.e. RF amplifier 250 is capable of generating a 10 W RF output signal). In this example, N is 5 (given by the output power of RF amplifier 250 divided by the output power of RF amplifier 240).

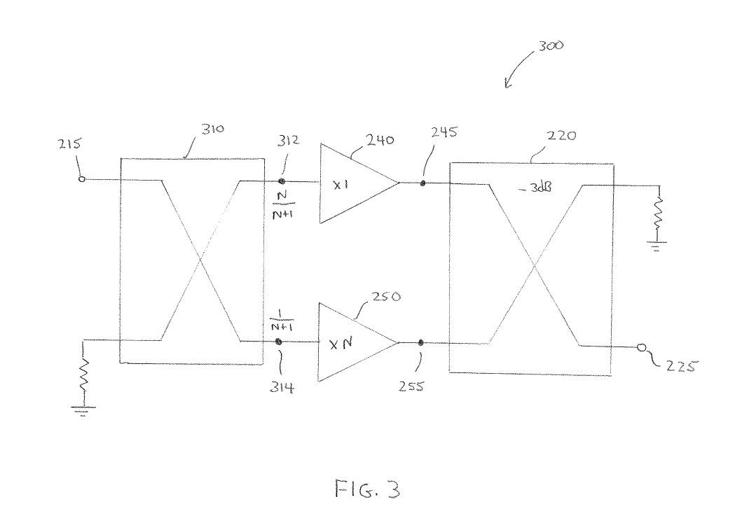

According to certain embodiments, when the output power of RF amplifiers 240 and 250 is represented by a power ratio of 1:N, the coupling factor of the input coupled signals provided at input coupler output ports 212, 214 can remain constant, as shown in FIG. 2. In other words, as discussed above, the amplitudes of the input coupled signals may be the same. In other embodiments, the coupling factor of the input coupled signals may be set to a selected coupling factor, for example [N/(N+1)] and [1/(N+1)], as shown in FIG. 3. In this case, the amplitudes of input coupled signals provided at the input coupler output ports 312, 314 of input coupler 310 may be different and determined according to the coupling factor. It is to be appreciated that the input couplers 210 and 310, shown in FIGS. 2 and 3 respectively, can adjust the coupling factor of the input coupled signals to permit the desired flow of power to RF amplifiers 240, 250. In certain examples, the coupling factor of the input coupled signals can be selected/fixed so as to allow for RF amplifier 240 to turn on substantially at the moment at which RF amplifier 250 compresses, or vice versa.

In the example illustrated in FIG. 3, the amplifier circuit 300 includes the input coupler 310 having a coupling factor of [N/(N+1)] and [1/(N+1)], while the output coupler 220 is a 3 dB coupler, as may be the case in amplifier circuit 200. With this particular arrangement, the input coupler 310 and output coupler 220 can be of the same or unequal coupling ratios. Having the input coupler 310 and the output coupler 220 of unequal coupling ratios may, for example, be advantageous if the amplifier circuit 300 spends most of its time at a particular input power. The input coupler 310 and the output coupler 220 can be also configured to match the output power of RF amplifiers 240 and 250. For example, if RF amplifier 240 is capable of generating a 1 W RF output signal and RF amplifier 250 is capable of generating a 3 W RF output signal, an efficient design may use an input coupler 310 to output coupler 220 ratio of 1:3. This may be achieved using a 1:3 combiner. It will be appreciated by those skilled in the art, given the benefit of this disclosure, that the combiner may be replaced with a splitter.

Additionally, the output coupler 220 may be configured such that the coupling factors at ports 245 and 255 are optimized for a desired point of peak PAE, rather than being equal and ½, ½ (as is the case with a 3 dB coupler), as shown in FIG. 3. For example, if the coupling factor at port 212 is N/(N+1), the coupling factor at port 255 may be set to N/(N+1) for maximum PAE at saturation. Alternatively, the coupling factor at port 255 may be set to 1/(N+1) to achieve maximum PAE at back-off. A designer may select the input power level for peak PAE by selecting a coupling factor between 1/(N+1) and N/(N+1). In all cases, the sum of the coupling factors at ports 245 and 255 is always equal to 1.

According to another embodiment, the RF amplifiers 240 and 250 may have the same output power characteristics but be biased differently such that the measurable output power of the amplifiers 240, 250 is not the same. For example, RF amplifiers 240, 250 can both have the same output power characteristic (e.g., RF amplifiers 240 and 250 are both capable of generating a 10 W RF output signal), but may be configured in a way that the bias of RF amplifier 240 (e.g., the bias of the drain of RF amplifier 240) is set lower than that of RF amplifier 250. With this arrangement, RF amplifier 240 can be configured to have a lower power rating than RF amplifier 250. For example, RF amplifier 240 can be biased to have an output power of 2 W while RF amplifier 250 can be biased to have a 10 W power rating. The above offers the same benefits as using two RF amplifiers 240, 250 of the same output power while providing for easier manufacture. The output power of RF amplifiers 240, 250 can also be varied relative to the magnitude of the RF input signal 230 received at input port 215.

In other embodiments, the amplifier circuit 200 or 300 may include more than two RF amplifiers. In particular, the amplifier circuit can be configured to include N number (or a plurality) of RF amplifiers, which can be configured in either series or parallel. In the case of an amplifier circuit with three amplifiers, for example, a power ratio can be represented by 1:X:Y, with 1 corresponding to a first amplifier, X corresponding to a second amplifier, and Y corresponding to a third amplifier. Additionally, a coupling factor of an amplifier circuit with three amplifiers can be represented by X/(X+Y+1), Y/(X+Y+1), 1/(X+Y+1) for the first amplifier, the second amplifier, and the third amplifier, respectively. Those skilled in the art will appreciate, given the benefit of this disclosure, that the above may be similarly extended to more than three RF amplifiers.

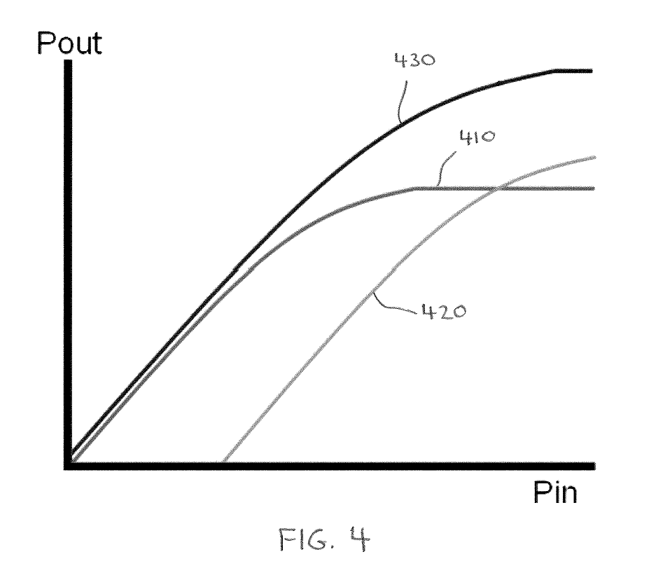

Referring now to FIG. 4, there are illustrated examples of power curves corresponding to the individual RF amplifiers 240, 250, and the amplifier circuit 200. In FIG. 4, trace 410 represents the power curve for RF amplifier 240, trace 420 represents the power curve for RF amplifier 250, and trace 430 represents the power curve for amplifier circuit 200. The power curves show the output power (Pout) from the respective amplifier or amplifier circuit as a function of the RF input power (Pin) received at input port 215. The power curves of amplifier circuit 300 may be the same as or similar to the power curve of amplifier circuit 200. The power curves 410, 420, and 430 may, for example, be achieved by: (1) biasing RF amplifier 240 into class A, class AB, or class B operation and biasing RF amplifier 250 into class C operation, wherein the power ratings of RF amplifiers 240 and 250 are substantially the same (represented by a 1:1 power ratio); (2) biasing RF amplifiers 240, 250 into the same class (e.g., class A, AB, or B operation), wherein the power ratings of RF amplifiers 240, 250 are substantially different (e.g., represented by a power ratio of 1:N); or (c) a combination of biasing RF amplifiers 240, 250 into the same or a different class of operation with the power ratios between RF amplifiers 240, 250 being dependent on the biasing and class of operation.

For example, at low input power levels, the output power of the amplifier circuit 200 may be supplied primarily by RF amplifier 240 and secondarily by RF amplifier 250, with the DC power consumed by the amplifier circuit 200 largely determined by RF amplifier 240. With this particular arrangement, the overall PAE at back-off is relatively high compared with overall PAE at back-off for conventional circuits. At high input power levels, the output power of the amplifier circuit 200 may be supplied substantially equally by RF amplifiers 240, 250 with each of RF amplifiers 240, 250 operating at peak PAE. With this particular arrangement, the overall PAE is relatively high compared with overall PAE at back-off for conventional amplifier circuits.

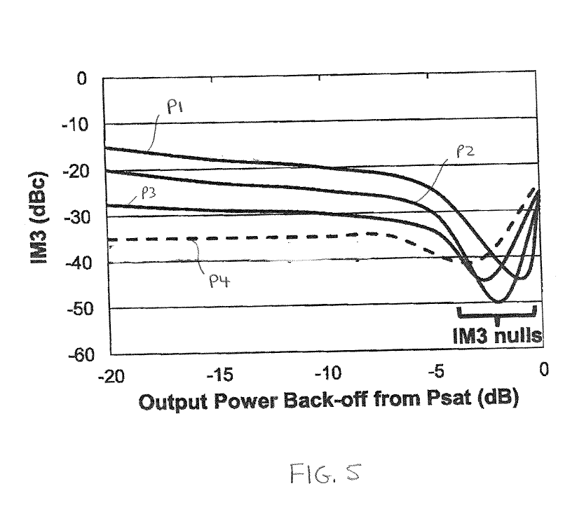

By appropriately selecting the class, bias, and power split ratio of the RF amplifiers 240, 250 in accordance with the concepts and techniques described herein, an amplifier circuit 200 or 300 may be achieved in which the output power from a first RF amplifier (e.g., RF amplifier 250) becomes more substantial as the output of a second RF amplifier (e.g., RF amplifier 240) begins to compress. With this particular arrangement, the power curve 430 of amplifier circuit 200 remains linear up to higher power levels. The point at which the power curves 410, 420 of RF amplifiers 240 and 250, respectively, intersect creates a relatively low IM3 point, as shown in FIG. 5. By reconfiguring any combination of the class, bias, and power split ratio of RF amplifiers 240, 250, the IM3 point can be adjusted to a desired input or output level, as illustrated by lines P1, P2, and P3 in FIG. 5. This technique thus achieves linearity deep into saturation while maintaining high efficiency. A 10-20 dB multi-octave linearity improvement has, for example, been shown near saturation. Additionally, the IM3 null may be placed at any desired back-off level. In contrast, dotted line P4 in FIG. 5 represents the traditional output power level associated with conventional circuits in which the two component amplifiers are equal in bias and power ratio, featuring poor linearity at saturation.

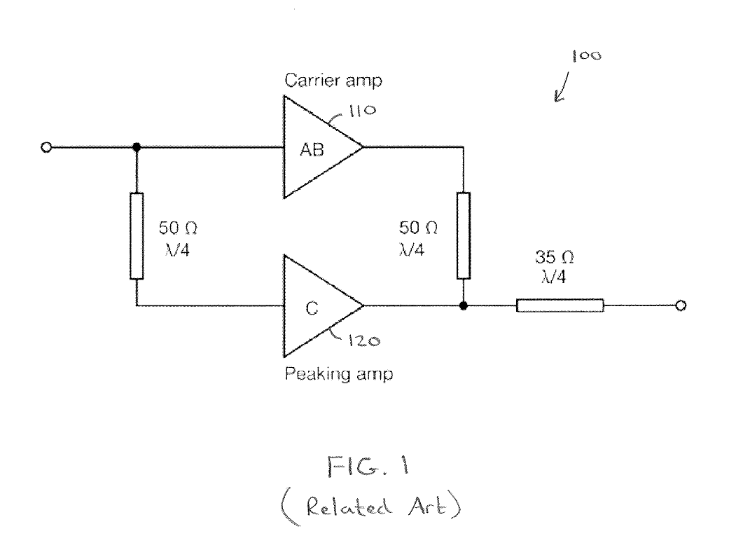

Amplifier circuits employing the concepts and techniques described herein, such as amplifier circuits 200 and 300, for example, may provide an extremely efficient solution for amplifying the complex modulation schemes employed in current and emerging wireless systems. The ability to reconfigure a minimum IM3 point can be found particularly useful for military and commercial applications where peak linearity over a range of waveforms and power levels are needed. Additionally, unlike conventional amplifier circuits such as that discussed above with reference to FIG. 1, amplifier circuits employing the concepts and techniques described herein may also have the advantage of not including bandwidth limiting elements. As discussed above, certain conventional amplifier circuits, such as that shown in FIG. 1, rely on a 90° degree phase shift between the two signals provided at the output ports of the input coupler, and are therefore inherently narrowband because the phase shift varies with frequency. In contrast, embodiments of the amplifier circuits disclosed herein achieve improved PAE at back-off, among other benefits, by changing bias and class of operation, as discussed above. No impedance transformation is necessary, and all the RF amplifiers (carrier, peaking, etc.) may be operating at approximately 50 ohms all the time. The relative phase between the signals provided to the two RF amplifiers 240, 250 is not relevant provided that the signals are not inverse. Accordingly, the bandwidth-limiting frequency dependence of conventional circuits is avoided. Thus, aspects and embodiments may provide amplifier circuits that are capable of operation over octave, decade, or multi-decade bandwidths while at the same time providing high PAE over a wide dynamic range. Additionally, there are no limits to maximum output power or material selection. For example, the amplifiers may be fabricated using GaN, GaAs, or SiGe materials.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A radio frequency (RF) amplifier circuit comprising:
an input coupler configured to receive an RF input signal and to generate at least two coupled signals;
a first RF amplifier configured to receive and amplify a first one of the at least two coupled signals to generate a first amplified signal, the first RF amplifier being biased into a first class of operation;
a second RF amplifier configured to receive and amplify a second one of the at least two coupled signals to generate a second amplified signal, the second RF amplifier being biased into a second class of operation; and
an output coupler configured to receive the first and second amplified signals and to generate an amplified output signal based on the first and second amplified signals;
wherein a power ratio between the first and second RF amplifiers is selected based on biasing of the first and second RF amplifiers, the first class of operation, and the second class of operation.

2. The RF amplifier circuit of claim 1 wherein the first class of operation is one of class A, class AB, and class B, and the second class of operation is class C.

3. The RF amplifier of claim 2 wherein the power ratio is 1:1.

4. The RF amplifier circuit of claim 3 wherein the input coupler and the output coupler are 3 dB couplers.

5. The RF amplifier circuit of claim 1 wherein the first class of operation is the same as the second class of operation, and wherein the first RF amplifier has a normalized power rating of 1 and the second RF amplifier has a normalized power rating of N, such that the power ratio is 1:N.

6. The RF amplifier circuit of claim 5 wherein the input coupler and the output coupler are 3 dB couplers.

7. The RF amplifier circuit of claim 5 wherein the input coupler has an input coupling factor selected to match the power ratio.

8. The RF amplifier circuit of claim 7 wherein the output coupler has an output coupling factor selected to match the power ratio.

9. The RF amplifier circuit of claim 5 wherein the input coupler is configured to provide the first one of the at least two coupled signals at a first port with a coupling factor of N/(N+1), and to provide the second one of the at least two coupled signals at a second port with a coupling factor of 1/(N+1), and wherein the first RF amplifier is connected to the first port to receive the first one of the at least two coupled signals, and the second RF amplifier is connected to the second port to receive the second one of the at least two coupled signals.

10. The RF amplifier circuit of claim 9 wherein the output coupler is a 3 dB coupler.

11. The RF amplifier circuit of claim 9 wherein the output coupler has a first input port connected to an output of the first RF amplifier to receive the first amplified signal, and a second input port connected to an output of the second RF amplifier to receive the second amplified signal, and the output coupler is configured with a coupling factor of N/(N+1) at the second input port and a coupling factor of [1−N/(N+1)] at the first input port.

12. The RF amplifier circuit of claim 9 wherein the output coupler has a first input port connected to an output of the first RF amplifier to receive the first amplified signal, and a second input port connected to an output of the second RF amplifier to receive the second amplified signal, and the output coupler is configured with a coupling factor of 1/(N+1) at the second input port and a coupling factor of [1−1/(N+1)] at the first input port.

13. The RF amplifier circuit of claim 1 wherein the first RF amplifier and the second RF amplifier are substantially the same and are biased differently such that the power ratio is less than or greater than one.

14. A radio frequency (RF) amplifier circuit comprising:
an input coupler configured to receive an RF input signal and to generate a plurality of coupled signals;
a plurality of RF amplifiers each connected to the input coupler and configured to receive and amplify one of the plurality of coupled signals to generate a corresponding plurality of amplified signals, each of the plurality of RF amplifiers being configurable as to a class of operation and biasing; and
an output coupler connected to the plurality of RF amplifiers and configured to receive the plurality of amplified signals and to generate an amplified output signal from the plurality of amplified signals, the amplified output signal being based on a combination of a selected class of operation of each of the plurality of RF amplifiers, the biasing of each of the plurality of RF amplifiers, and a power ratio between the plurality of RF amplifiers.

15. The RF amplifier circuit of claim 14 wherein the plurality of RF amplifiers includes a first RF amplifier having a normalized power rating of 1, a second RF amplifier having a normalized power rating of X, and a third RF amplifier having a normalized power rating of Y, and wherein the power ratio is 1:X:Y.

16. The RF amplifier circuit of claim 15 wherein the input coupler has an input coupling factor selected to match the power ratio.

17. The RF amplifier circuit of claim 15 wherein the output coupler has an output coupling factor selected to match the power ratio.

18. The RF amplifier circuit of claim 14 wherein the plurality of RF amplifiers are biased such that the power ratio is less than or greater than one.
